(19) United States
(12) Patent Application Publication
(10) Pub. No.: US 2016/0005892 A1
(43) Pub. Date: Jan. 7, 2016

(54) VERTICAL PILLAR STRUCTURE PHOTOVOLTAIC DEVICES AND METHOD FOR MAKING THE SAME

(71) Applicant: ZENA TECHNOLOGIES, INC., Cambridge, MA (US)

(72) Inventor: Young-June Yu, Cranbury, NJ (US)

(21) Appl. No.: 14/322,503

(22) Filed: Jul. 2, 2014

(51) Int. Cl. H01L 31/0352; H01L 31/18; H01L 31/072

(52) U.S. Cl. CPC H01L 31/03529; H01L 31/072; H01L 31/18

(57) ABSTRACT

Thin substrate photovoltaic and methods for making them are disclosed herein. In an embodiment, a photovoltaic device may include a substrate comprising a semiconductor material, one or more core structures, each extending essentially perpendicularly from a first surface of the substrate such that the core structures and the substrate form a single crystal, a shell layer disposed at least on a portion of a sidewall of the core structures and on the first surface, and a conductive layer disposed between adjacent core structures. The conductive layer forms an ohmic contact with the shell layer disposed on the first surface and between the adjacent core structures.

### RELATED APPLICATIONS

The disclosures of U.S. patent application Ser. No. 12/204,686, filed Sep. 4, 2008 (now U.S. Pat. No. 7,646,943), Ser. No. 12/648,942, filed Dec. 29, 2009 (now U.S. Pat. No. 8,229,255), Ser. No. 13/556,041, filed Jul. 23, 2012, Ser. No. 12/270,233, filed Nov. 13, 2008 (now U.S. Pat. No. 8,274,039), Ser. No. 13/925,429, filed Jun. 24, 2013, Ser. No. 13/570,027, filed Aug. 8, 2012 (now U.S. Pat. No. 8,471,190), Ser. No. 12/472,264, filed May 26, 2009 (now U.S. Pat. No. 8,269,985, Ser. No. 13/621,607, filed Sep. 17, 2012 (now U.S. Pat. No. 8,514,411), Ser. No. 13/971,523, filed Aug. 20, 2013 (now allowed), Ser. No. 12/472,271, filed May 26, 2009 (now abandoned), Ser. No. 12/478,598, filed Jun. 4, 2009 (now U.S. Pat. No. 8,546,742), Ser. No. 14/021,672, filed Sep. 9, 2013, Ser. No. 12/573,582, filed Oct. 5, 2009 (now allowed), Ser. No. 14/274,448, filed May 9, 2014, Ser. No. 12/575,221, filed Oct. 7, 2009 (now U.S. Pat. No. 8,384,007), Ser. No. 12/633,323, filed Dec. 8, 2009 (now U.S. Pat. No. 8,735,797), Ser. No. 14/068,864, filed Oct. 31, 2013, Ser. No. 14/281,108, filed May 19, 2014, Ser. No. 13/494,661, filed Jun. 12, 2012 (now U.S. Pat. No. 8,754,359), Ser. No. 12/633,318, filed Dec. 8, 2009 (now U.S. Pat. No. 8,519,379), Ser. No. 13/975,553, filed Aug. 26, 2013 (now U.S. Pat. No. 8,710,488), Ser. No. 12/633,313, filed Dec. 8, 2009, Ser. No. 12/633,305, filed Dec. 8, 2009 (now U.S. Pat. No. 8,299,472), Ser. No. 13/543,556, filed Jul. 6, 2012 (now allowed), Ser. No. 12/621,497, filed Nov. 19, 2009 (now abandoned), Ser. No. 12/633,297, filed Dec. 8, 2009, Ser. No. 12/982,269, filed Dec. 30, 2010, Ser. No. 12/966,573, filed Dec. 13, 2010, Ser. No. 12/967,880, filed Dec. 14, 2010 (now U.S. Pat. No. 8,748,799), Ser. No. 12/966,514, filed Dec. 13, 2010, Ser. No. 12/974,499, filed Dec. 21, 2010 (now U.S. Pat. No. 8,507,840), Ser. No. 12/966,535, filed Dec. 13, 2010, Ser. No. 12/910,664, filed Oct. 22, 2010, Ser. No. 12/945,492, filed Nov. 12, 2010, Ser. No. 13/047,392, filed Mar. 14, 2011 (now allowed), Ser. No. 13/048,635, filed Mar. 15, 2011 (now allowed), Ser. No. 13/106,851, filed May 12, 2011, Ser. No. 13/288,131, filed Nov. 3, 2011, Ser. No. 14/032,166, filed Sep. 19, 2013, Ser. No. 13/543,307, filed Jul. 6, 2012, Ser. No. 13/963,847, filed Aug. 9, 2013, Ser. No. 13/693,207, filed Dec. 4, 2012, and 61/869,727, filed Aug. 25, 2013, are each hereby incorporated by reference in their entirety.

### FIELD OF INVENTION

The present disclosure is related to photovoltaic devices and methods of making the same.

### BACKGROUND

Monocrystalline silicon solar cells dominate the photovoltaic market because of their high efficiency, low production cost, and reliable and durable performance in harsh environments. A further reduction in costs is, however, needed to keep silicon solar cells competitive in photovoltaic market. A reduction of production costs generally includes simplifying the process and reducing the amount of material used. Thinning the substrate can be a solution for reducing the material cost. Thin semiconductor substrates have not been favored for solar cell production because of the following two key issues. First, since some percentage of photons penetrate deep into a planar substrate, at least 100 μm is needed for absorption of all light energy. A substrate with thickness less than that value will result in reduced efficiency. Secondly, a substrate thinner than 100 μm is fragile and can get damaged easily during the fabrication process.

### SUMMARY

In an embodiment, a photovoltaic device is disclosed. The photovoltaic device includes a substrate comprising a semiconductor material, one or more core structures, each extending essentially perpendicularly from a first surface of the substrate such that the core structures and the substrate form a single crystal, a shell layer disposed at least on a portion of a sidewall of the core structures and on the first surface, and a conductive layer disposed between adjacent core structures. The conductive layer forms an ohmic contact with the shell layer disposed on the first surface and between the adjacent core structures.

In an embodiment, a method of making a photovoltaic device is described. The method includes obtaining a plurality of core structures, each extending essentially perpendicularly from a substrate such that the substrate and the plurality of core structures form a single crystal, disposing a shell layer adjacent at least a portion of a sidewall of each of the plurality of core structures, disposing a passivation layer substantially encapsulating the shell layer, disposing a conductive layer between neighboring core structures substantially encapsulating the passivation layer, and forming an ohmic contact between the conductive layer and the shell layer between the adjacent core structures by ablating the passivation layer using laser ablation.

In an embodiment, a method of making a photovoltaic device is described. The method includes mounting on a first carrier substrate, a device substrate having a plurality of structures extending essentially perpendicularly from a first surface thereof, disposing an ultra-violet (UV) removable adhesive on the device substrate such the plurality of structures and the first surface are substantially fully encapsulated by the UV removable adhesive, contacting a second carrier substrate with the UV removable adhesive at a surface opposite the first surface, unmounting the device substrate from the first carrier substrate to provide a second surface, contacting the second surface with a conductive surface of a mounting surface, and removing the second carrier surface by exposing the UV removable adhesive to UV radiation.

This disclosure is not limited to the particular systems, devices and methods described, as these may vary. The terminology used in the description is for the purpose of describing the particular versions or embodiments only, and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

### BRIEF DESCRIPTION OF THE DRAWINGS

In the present disclosure, reference is made to the accompanying drawings, which form a part hereof. In the drawings, similar symbols typically identify similar components, unless context dictates otherwise. Various embodiments described in the detailed description, drawings, and claims are illustrative and not meant to be limiting. Other embodiments may be used, and other changes may be made, without departing from the spirit or scope of the subject matter presented herein. It will be understood that the aspects of the present disclosure, as generally described herein, and illustrated in the Figures, can be arranged, substituted, combined, separated, and designed in a wide variety of different configurations, all of which are contemplated herein.

FIG. 1 illustrates a cross-section view a photovoltaic device 100 according to an embodiment of the present disclosure.

FIG. 2 illustrates a photovoltaic device with a thin single crystal silicon substrate and vertical core-shell p-n junctions according to an embodiment of the present disclosure.

FIGS. 3A-3W schematically illustrate various steps during an exemplary process for fabrication of photovoltaic device illustrated in FIG. 2, in accordance with various embodiments of the present disclosure.

FIG. 4 illustrates a cross-section of a photovoltaic device with a thin single crystal silicon substrate and vertical core-shell heterojunctions according to an embodiment of the present disclosures.

FIGS. 5A-5P schematically illustrate various steps during an exemplary process for fabrication of photovoltaic device illustrated in FIG. 4, in accordance with various embodiments of the present disclosure.

FIG. 6 illustrates a cross-section of a photovoltaic device with a thin single crystal gallium arsenide substrate and vertical core-shell p-n junctions according to an embodiment of the present disclosures.

### DETAILED DESCRIPTION

Vertical nano- or micro-core-shell type pillar structures improve charge collection efficiency following light absorption through optical waveguide effect. Such structures, therefore, improve the quantum efficiency of photovoltaic devices, thereby increasing their photo-conversion efficiency. Such structures fabricated on thin substrates can greatly reduce cost while simultaneously increasing the conversion efficiency of photovoltaic devices. Described herein are photovoltaic devices having vertical core-shell pillar structures on a thin substrate and methods of making the same.

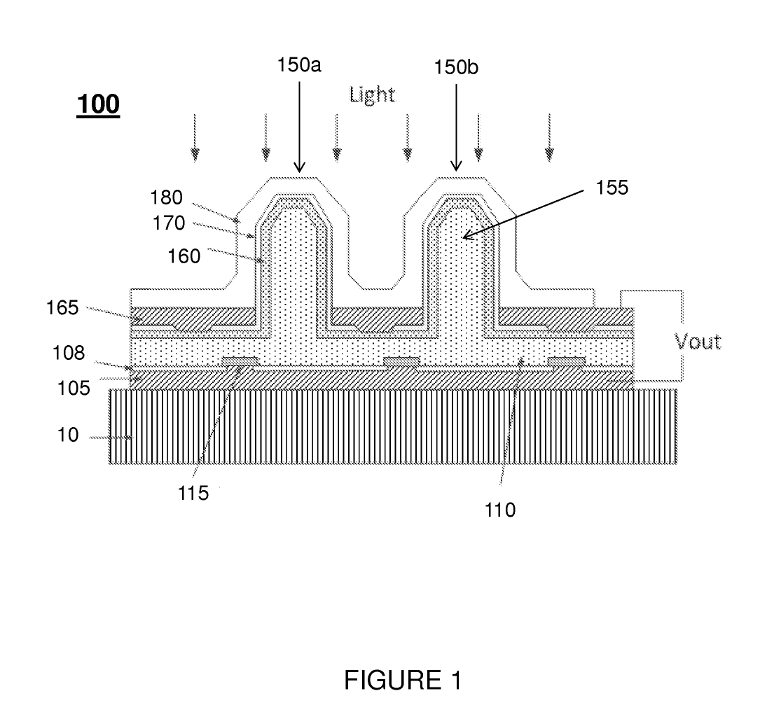

FIG. 1 illustrates a cross-section view a photovoltaic device 100 according to an embodiment. Photovoltaic device 100 is mounted on a mounting substrate 10 and includes a metal layer 105 in contact with mounting substrate 10, and a substrate 110 having ohmic contacts 115 with metal layer 105. Pillar structures 150a and 150b extend essentially perpendicularly from substrate 110 and include a semiconductor core 155, a shell layer 160, a passivation layer 170 and an optical clad 180. An electrically conductive layer 165 is disposed in the space between neighboring pillar structures 150a and 150b, and between passivation layer 170 and optical clad 180. Electrically conductive layer 165 forms an ohmic contact between shell layer 160 and a top-side electrode (not explicitly shown) of photovoltaic device 100. Metal layer 105 forms a bottom-side electrode (not explicitly shown) of photovoltaic device 100.

In various embodiments, substrate 110 may be composed of group IV semiconductors such as, for example, silicon (Si) or Germanium (Ge); group III-V semiconductors such as, for example, gallium arsenide (GaAs), aluminum arsenide (AlAs), indium phosphide (InP), and/or the like; group II-VI semiconductors such as, for example, cadmium sulfide (CdS), cadmium telluride (CdTe), zinc oxide (ZnO), and/or the like; quaternary semiconductors such as, for example, aluminum gallium arsenide (AlGaAs), indium gallium phosphide (InGaP), aluminum indium phosphide (AlInP), and/or the like; and/or any combination thereof. Substrate 110 may be single crystalline, polycrystalline or amorphous in various embodiments. It is contemplated that substrate 110 may be intrinsic (undoped), p-type lightly doped, p-type heavily doped, n-type lightly doped or n-type heavily doped semiconductor.

Core 155 may be formed of essentially the same material as substrate 110. In some embodiments, there are substantially no grain boundaries at the interface of core 155 and substrate 110. In other words, in such embodiments, core 155 and substrate 110 are formed from a single crystal. One of ordinary skill in the art will recognize that core 155 may be formed by selectively etching or otherwise removing portions of substrate 110. The skilled artisan will also recognize that alternatively, or additionally, core 155 may be formed by epitaxially growing the material of substrate 110 on portions of substrate 110. It is contemplated that core 155 and substrate 110 may also be formed from polycrystalline materials, and may be monolithically formed from a single piece of polycrystalline material. It is further contemplated that depending on particular materials used, shell layer 160 and core 155 (along with substrate 110) may form a p-n junction.

In various embodiments, substrate 110 and shell layer 160 may be the same semiconductor doped with dopants of opposite polarity. For example, substrate 110 and shell layer 160 may both be single crystal silicon with substrate 110 being doped with a p-type dopant such as indium (In) and shell layer 160 being doped with an n-type dopant such as phosphorus (P). Doping levels of substrate 110 and shell layer 160 may be varied in different embodiments. For example, in an embodiment, shell layer 160 may be a heavily doped n+semiconductor. In an embodiment, for example, substrate 110 may be a p-type semiconductor and have a thickness in the range of about 1 μm to about 50 μm. In such an embodiment, shell layer 160 may be an n-type semiconductor.

In some embodiments, shell layer 160 may comprise two layers, e.g., an intrinsic amorphous semiconductor and a heavily doped amorphous semiconductor. The base semiconductor material of shell layer 160 may be the same as that of substrate 110 and core 155, while dopant and doping levels may vary. Likewise, electrically conductive layer 165 may, in some embodiments, comprise two layers, e.g., a transparent conducting layer and a metal layer.

In an embodiment, shell layer 160 may be a heavily doped n+-type semiconductor and core 155 may be a lightly doped p-type semiconductor. As carriers travel from the heavily doped n+shell to lightly doped p-type core, a depletion layer is formed in the core and the shell layer, thereby forming a p-n junction. Appropriate thickness of shell layer 160 will depend on the thickness of depletion layer formed within it. One of ordinary skill in the art will recognize that choice of thickness for shell layer 160 depends on various factors such as, for example, doping level of semiconductor core 155 and of shell layer 160; particular dopants (if any) used for doping core 155 and shell layer 160; process parameters and compatibility; and/or the like.

Electrically conductive layer 165 may be composed of any suitable metal compatible with the manufacturing process used for making photovoltaic device 100. For example, it is well known that aluminum (Al) provides good electrical contacts in microelectronic circuits and is compatible with most fabrication processes. On the other hand, gold (Au) may diffuse into a semiconductor substrate if the fabrication process includes a heating step, particularly if the temperature is raised above about 120° C. Gold, in such instances, may not be the best choice for electrically conductive layer 165. Suitable metals include, but are not limited to, aluminum (Al), nickel (Ni), gold (Au), silver (Ag), copper (Cu), titanium (Ti), palladium (Pd), platinum (Pt), and the like, and/or any combinations thereof.

Optical clad layer 180 in various embodiments may improve the efficiency of photovoltaic device 100 by creating an optical waveguide effect and preventing the radiation coupled to vertical pillar structures 150a and 150b from scattering out. Suitable materials for optical clad layer 180 include transparent polymers having a refractive index lower than that of the individual vertical junction, such as, for example, polydimethyl siloxane (PDMS), polymethyl methacrylate (PMMA), polyethylene terephthalate (PET), and the like, and/or any combinations thereof. Other suitable materials include, but are not limited to, Al₂O₃, HfO₂, SiO₂, MgF₂, SnO, doped SnO, ZnO, doped ZnO, and the like, and/or any combinations thereof.

Without wishing to be bound by theory, it is contemplated that one of the purposes of the optical clad layer is to increase the optical waveguide effect and couple more light to the pillar structures. Thus, in some embodiments, it may be desirable to have the optical clad layer thickness such that the evanescent waves emerging out from the optical clad layer are substantially negligible.

Any suitable insulating material may be used for providing passivation layer 170. It will be understood by one of ordinary skill in the art that factors such as compatibility with fabrication process as well as other materials used in fabricating the device determine the suitability of the insulating material. For example, if the semiconductor core is silicon, the passivation layer can be silicon dioxide (SiO₂) or silicon nitride (Si₃N₄). Other examples of materials suitable for passivation layer 170 include, but are not limited to, oxides such as Al₂O₃, HfO₂, MgF₂, SnO₂, ZnO, and the like; various transparent polymers such as PDMS, PMMA, PET, and the like; and/or any combinations thereof. In various embodiments, it may be desirable that passivation layer 170 be transparent, at least to electromagnetic radiation in the visible, infrared and ultraviolet spectra.

In general, pillar structures 150a and 150b of photovoltaic device 100 may have any shape or size. For example, a cross-section of the pillar structures may have a shape of a circle, an ellipse, a convex polygon, a mesh, and the like, or any combination thereof. Likewise, the pillar structures may be shaped as a cylinder, a frustum, a cone, a prism, and the like, and/or any combination thereof.

Because the probability of carrier generation increases the longer the radiation propagates through the semiconductor core, it may be advantageous to provide the semiconductor cores an aspect ratio greater than one (thereby, providing a waveguide effect). Aspect ratio is typically defined as the ratio of a dimension perpendicular to the substrate to a dimension parallel to the substrate. In case of the photovoltaic devices described herein, the aspect ratio may be defined as the ratio of height to diameter (or a side-length in case of a polygonal cross-section) of the pillar structures. An aspect ratio greater than one, thus, may result in increasing the quantum efficiency of the photovoltaic device by enhancing the optical waveguide effect of the pillar structures. Another approach to enhancing the optical waveguide effect may be rounding or tapering the semiconductor core structures. Without wishing to be bound by theory, it is contemplated that such structure may be advantageous by reflecting the back-scattered light back into the core structure and further improving the quantum efficiency of the photovoltaic device.

One skilled in the art will recognize that a main purpose of mounting substrate being merely to provide strength and mechanical stability to photovoltaic device 100, a relatively low-cost material that serves this purpose can, generally, be used for mounting substrate 10. For example, in an embodiment, mounting substrate 10 may be glass or a polymer such as acrylic, or polyethylene. It will also be understood by one of ordinary skill in the art that an insulating material is preferable for mounting substrate 10.

Substrate 110 can be disposed on mounting substrate 10 using a suitable metal layer 105. Metal layer 105 mainly serves two purposes: (i) as an adhesive between mounting substrate 10 and substrate 110, and (ii) as a bottom-side electrode for photovoltaic device 100. Any suitable metal may be used for metal layer 105. For example, a metal such as, for example, Ag, Au, Cu, Al, Ti, Cr, Ni, Pt, Pd, and the like, and/or any combination thereof may be used for metal layer 105.

Depending on the specific metal used for metal layer 105 and the process used for fabrication, there may be some metal diffusion into the semiconductor of substrate 110. This may be detrimental to the performance of photovoltaic device 100. Accordingly, in some embodiments, substrate 110 may be separated from metal layer 105 by a second passivation layer 108. Any suitable material may be used for second passivation layer 108. For example, if substrate 110 is silicon, an insulator such as SiO₂, or Si₃N₄ may be used for second passivation layer 108. Other materials similar to those used for passivation layer 170 may be used for second passivation layer 108.

Typically, a metal does not form ohmic contact with a semiconductor, particularly an intrinsic or a lightly doped semiconductor, because of formation of a Schottky barrier junction at the metal-semiconductor interface. Thus, depending on the particular materials being used for substrate 110 and metal layer 105, in some embodiments, it may be desirable to provide ohmic contacts 115 between metal layer 105 and substrate 110. Any suitable material may, however, be used for ohmic contacts 115. One of ordinary skill in the art will understand that the choice of material for ohmic contact 115 will depend on specific materials used for metal layer 105 and substrate 110. For example, if substrate 105 is an n-type semiconductor, ohmic contact 115 may be a heavily doped n+semiconductor and likewise, if substrate 105 is a p-type semiconductor, ohmic contact 115 may be a heavily doped p+semiconductor. Ohmic contact 115 may be deposited on to substrate 105 using a suitable method, or may be formed by diffusing an appropriate dopant in a selected area of substrate 105.

It is contemplated that an ohmic contact layer may replace the electrically conductive layer or alternatively be added between the electrically conductive layer and the shell layer and/or the passivation layer. Likewise, it is contemplated that other additional layers may be included in the photovoltaic device depending on materials and processes used in making the photovoltaic devices. For example, in an embodiment, a transparent conducting oxide layer may replace the passivation layer, or alternatively be added between the shell layer and the optical clad. Other configurations are also contemplated.

Embodiments illustrating the methods and materials used may be further understood by reference to the following non-limiting examples:

### EXAMPLES

### Example 1

### Photovoltaic Device with Thin Silicon Substrate and Vertical Core-Shell p-n Junctions

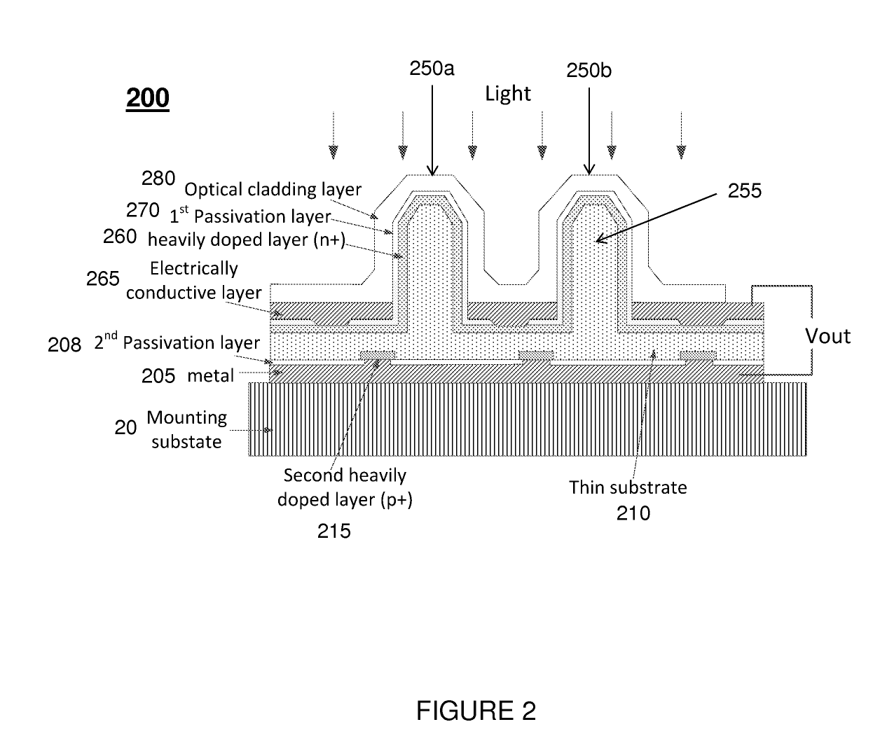

FIG. 2 illustrates a cross-section of a photovoltaic device 200 with a thin single crystal silicon substrate and vertical core-shell p-n junctions. Photovoltaic device 200 is mounted on a mounting substrate 20 and includes a metal layer 205 in contact with mounting substrate 20, and an intrinsic or a lightly p-doped single crystal silicon substrate 210 having heavily doped (p+) contacts 215 with bottom metal layer 205. Pillar structures 250a and 250b extend essentially perpendicularly from substrate 210 and include a semiconductor core 255, a heavily doped (n+) (e.g., epitaxially grown) silicon shell layer 260, a silicon dioxide passivation layer 270 and a PDMS optical clad 280. An electrically conductive aluminum layer 265 is disposed in the space between neighboring pillar structures 250a and 250b, and between passivation layer 270 and optical clad 280. Electrically conductive layer 265 forms an ohmic contact between shell layer 260 and a first electrode (not explicitly shown) of photovoltaic device 200. Bottom metal (e.g., aluminum) layer 205 forms a contact for a second electrode (not explicitly shown) of photovoltaic device 200. In some embodiments of this example, a second insulating passivation layer 208 may be included between substrate 210 and bottom metal layer 205.

Pillar structures 250a and 250b may be cylindrical and have a diameter in the range of about 1 μm to about 10 μm. One of ordinary skill in the art will understand that pillar structures of particular diameter may be better suited for absorption of light of certain frequencies. Thus, it may be desirable to provide an array of pillar structures having varying diameters so as to increase absorption efficiency across the visible spectrum. Accordingly, photovoltaic device 200 may have pillar structures having various diameters in the range described herein. For example, the cylindrical pillars may have a diameter of about 1 μm, about 1.1 μm, about 1.2 μm, about 1.3 μm, about 1.4 μm, about 1.5 μm, about 2 μm, about 2.5 μm, about 3 μm, about 3.5 μm, about 4 μm, about 5 μm, about 6 μm, about 7 μm, about 8 μm, about 9 μm, about 10 μm, or any other diameter or range of diameters between any two of these diameters.

Likewise, it may be desirable to vary the space between adjacent pillar structures. For example, the pillar structures may have a center-to-center distance ranging from about 2 μm to about 20 μm. Photovoltaic device 200 may have various portions of the substrate having pillar structures spaced by various distances. For example, the pillars may be spaced by about 2 μm on a first quadrant of the device, by about 4 μm on a second quadrant of the device, by about 8 μm on a third quadrant of the device, and by about 16 μm on a fourth quadrant of the device. Other distances are also contemplated, and include but are not limited to, about 3 μm, about 4 μm, about 5 μm, about 6 μm, about 7 μm, about 8 μm, about 9 μm, about 10 μm, about 11 μm, about 12 μm, about 13 μm, about 14 μm, about 15 μm, about 16 μm, about 17 μm, about 18 μm, about 19 μm, about 20 μm, or any other distance or range of distances between any two of these distances. Likewise, the substrate of the photovoltaic device may be sub-divided into any number of portions such as, for example, 2, 3, 4, 5, 6, 7, 8, 10, 15, 20, 25, 30, 50, 100, or any other number or range of numbers between any two of these numbers.

Pillar structures 250a and 250b may extend between about 1 μm to about 20 μm from the substrate. In other words, pillar structures 250a and 250b may have a height in the range of about 1 μm to about 20 μm. It is contemplated that the pillar structures may have any height within this range and that a particular photovoltaic device may have pillar structures of various heights within this range. For example, the pillar structures may have a height of 1 μm, about 1.1 μm, about 1.2 μm, about 1.3 μm, about 1.4 μm, about 1.5 μm, about 2 μm, about 2.5 μm, about 3 μm, about 3.5 μm, about 4 μm, about 5 μm, about 6 μm, about 7 μm, about 8 μm, about 9 μm, about 10 μm, about 11 μm, about 12 μm, about 13 μm, about 14 μm, about 15 μm, about 16 μm, about 17 μm, about 18 μm, about 19 μm, about 20 μm, or any other height or range of heights between any two of these heights.

Pillar structures of different heights may be uniformly or non-uniformly distributed across the substrate. As in case of pillar diameter and distance between pillar structures, a portion of the substrate may pillar structures all having substantially the same height. In other embodiments, a portion of the substrate may have pillar structures with a distribution of heights. For example, heights of pillar structures may increase monotonically (linearly or according to any other function) along one direction and may be substantially the same along a perpendicular direction. Other distributions are also contemplated.

Heavily doped shell layer 260 may have a thickness ranging from about 20 nm to about 400 nm. One of ordinary skill in the art will appreciate that the choice of thickness for shell layer 160 will depend on various factors, including but not limited to, type of dopant and level of doping in the shell layer as well as the core. In some embodiments, for example, shell layer 260 may have a thickness of about 20 nm, about 40 nm, about 80 nm, about 100 nm, about 150 nm, about 200 nm, about 225 nm, about 250 nm, about 300 nm, about 350 nm, about 400 nm, or any thickness or range of thicknesses between any two of these thicknesses.

The passivation layers (208 and 270) may have a thickness ranging from about 2 nm to about 150 nm depending on the materials and processes used in fabricating the photovoltaic device. In an example embodiment, both passivation layers 270 and 208 may have a thickness of about 2 nm, about 4 nm, about 8 nm, about 10 nm, about 15 nm, about 20 nm, about 30 nm, about 50 nm, about 100 nm, about 125 nm, about 150 nm, or any thickness or range of thicknesses between any two of these thicknesses. Thickness of passivation layer 270 and passivation layer 208 may be different in some embodiments.

Depending on particular material used for the optical clad layer, more particularly, depending on the refractive index of the material, optical clad layer 280 may have a thickness in range from about 100 nm to about 500 nm. For example, optical clad may have a thickness of about 100 nm, about 125 nm, about 150 nm, about 200 nm, about 250 nm, about 300 nm, about 350 nm, about 400 nm, about 450 nm, about 500 nm, or any thickness or range of thicknesses between any two of these thicknesses.

Substrate thickness may range from about 1 μm to about 50 μm. As discussed elsewhere herein, thinner substrates have advantages and disadvantages. Advantages stem from cost savings, while disadvantages stem from reduced mechanical strength and difficulty in handling resulting in breakage and losses. However, an appropriate process that allows effective and lossless handling of thin substrates can reduce manufacturing costs.

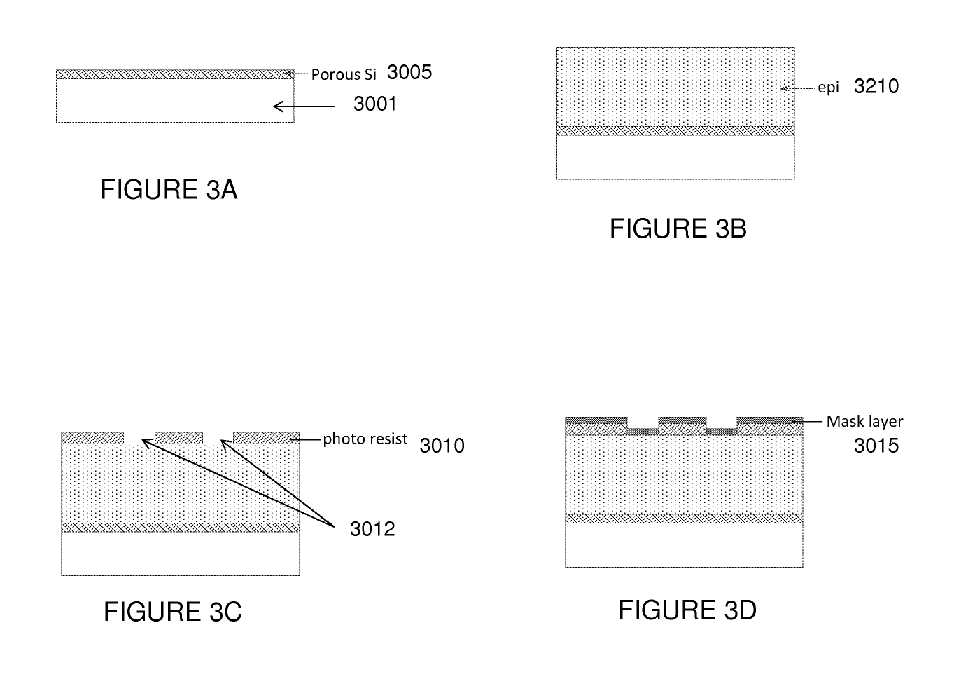

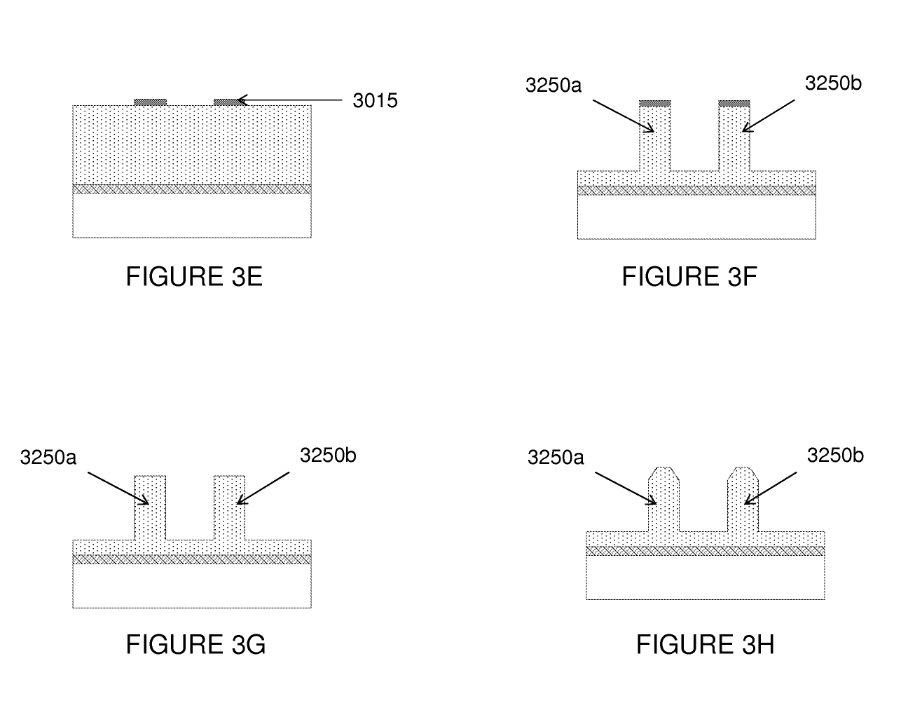

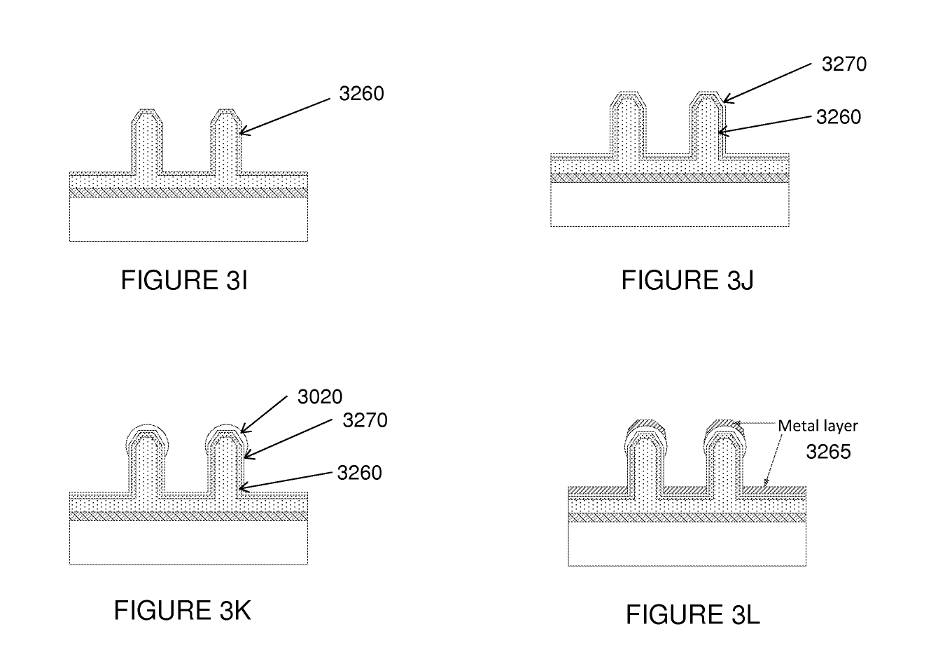

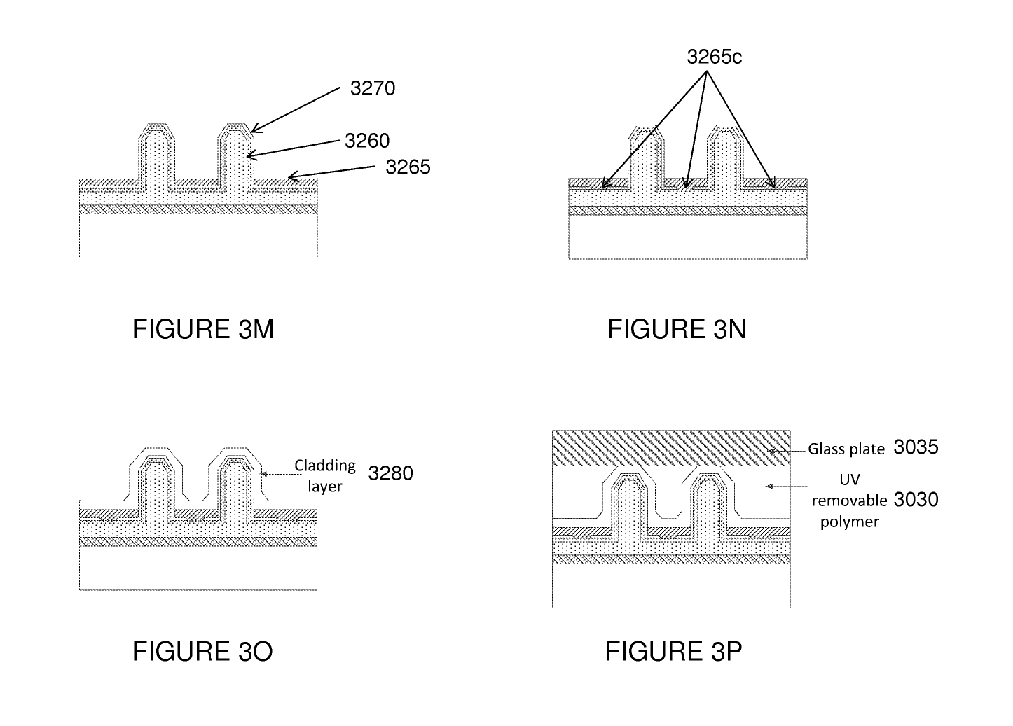

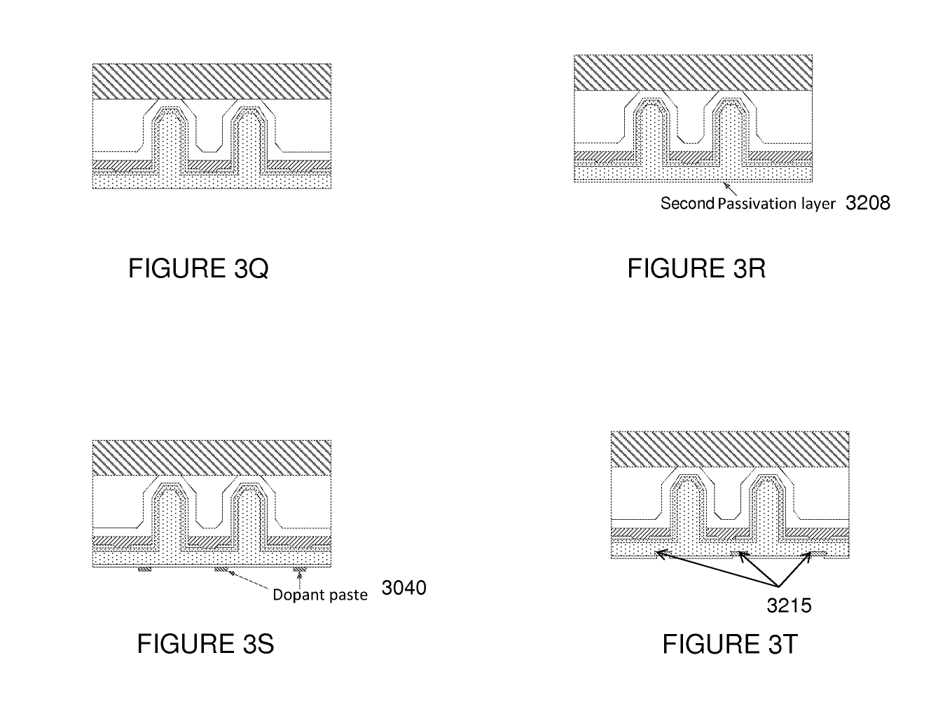

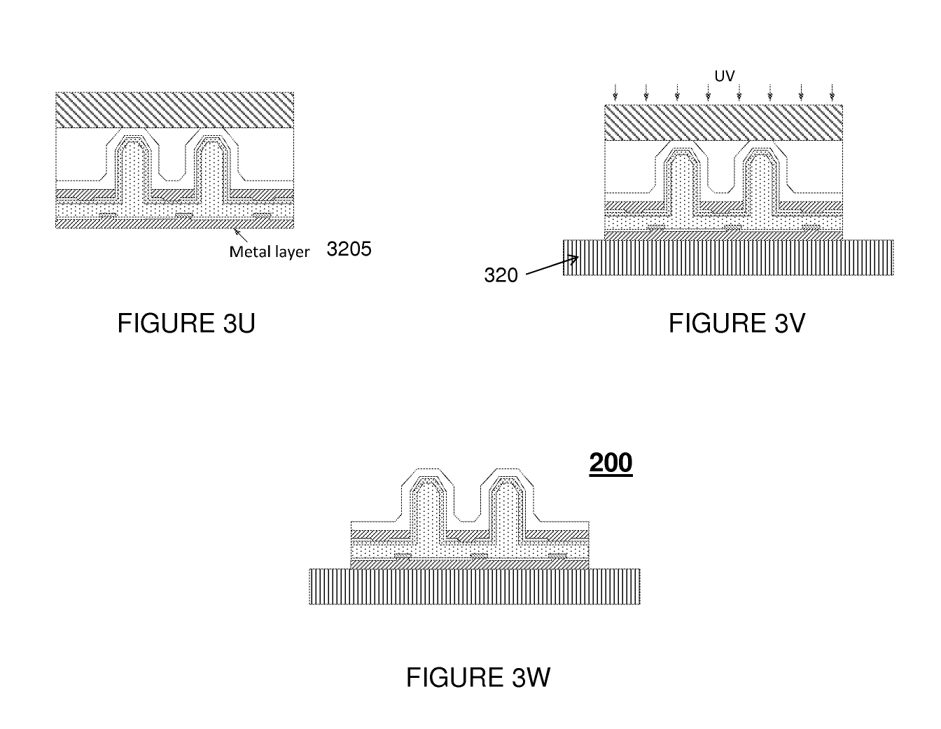

FIGS. 3A-3W schematically illustrate various steps during an exemplary process for fabrication of photovoltaic device 200 (or other like devices) illustrated in FIG. 2, in accordance with various embodiments of the present disclosure. FIG. 3A illustrates a crystalline silicon substrate 3001 covered with a porous silicon layer 3005 having a thickness of about 0.5 μm to about 2 μm.

An epitaxial silicon layer 3210 (illustrated in FIG. 3B) is grown on porous silicon layer 3005 to a thickness of about 10 μm to about 20 μm. Any suitable process known in the art (e.g., liquid phase epitaxy, vapor phase epitaxy, or solid phase epitaxy, or molecular-beam epitaxy, and the like) may be used for growing the epitaxial silicon layer. This is followed by spin coating a suitable photoresist layer 3010 and lithography to form openings 3012 (illustrated in FIG. 3C) through which the substrate 3210 is exposed. Depending on the desired geometry of pillar structures, the shape of the openings can be circular, or any other shape such as, for example, elliptical, or any convex polygonal shape. It is contemplated that a photovoltaic device may have an array of pillar structures having different geometries and may be fabricated by creating an array of openings having various geometries.

FIG. 3D illustrates an etch mask layer 3015 deposited over the remaining portion of photoresist layer 3010 and the exposed portion of substrate 3210. Etch mask layer 3015 can be a metal such as Al, Cr, Au, and the like, and/or a dielectric such as SiO₂, Si₃N₄, and the like, and can be deposited using any suitable process physical evaporation such as, thermal evaporation, electron-beam evaporation, sputtering, and the like, and/or chemical deposition such as chemical vapor deposition (CVD), plasma enhanced chemical vapor deposition (PECVD), and the like.

The remainder of photoresist is then lifted-off by a suitable solvent (e.g., acetone, or the like) and/or ashed in a resist asher to leave behind etch-mask layer 3015 directly on substrate 3210 (as illustrated in FIG. 3E) such that a portion of the substrate remains exposed. The exposed portion of the substrate is etched using a suitable dry or wet etch method to a desired depth to form pillar structures 3250a and 3250b (as illustrated in FIG. 3F). The pillar structures correspond to the unexposed area (i.e., area not covered by the etch mask layer) of the substrate. These pillar structures form silicon core 255 for vertical p-n junctions 250a and 250b of photovoltaic device 200. Examples of a dry etch process include, but are not limited to, inductively coupled plasma reactive ion etch (ICP RIE) process, or Bosch process. Examples of wet etch process include, but are not limited to, metal assisted chemical etch (MACE) process. One of ordinary skill in the art will be able to choose a suitable etch process depending on other factors such as the particular materials being used and the desired dimensions of various structures to be fabricated.

FIG. 3G illustrates pillar structures 3250a and 3250b after removal of the etch mask layer. Removal of the etch mask layer can be achieved using any suitable wet or dry etch process depending on the particular material of the etch mask layer. In an embodiment, the pillar structures 3250a and 3250b may be rounded or tapered off (as illustrated in FIG. 3H) using a suitable wet or dry etching technique. Without wishing to be bound by theory, it is contemplated that rounding or tapering the pillar structures may enhance the waveguide effect in the pillar structures, thereby increasing the quantum efficiency of the device. The entire height or a top portion of pillar structures may be rounded or tapered.

Heavily doped shell layer 3260 is formed by isotropically doping the surface of the pillar structures and the top surface of substrate 3210 as illustrated in FIG. 3I. Any suitable isotropic doping method such as, for example, thermal diffusion, may be used for doping the pillar structures and the substrate. In the example of photovoltaic device 200, shell layer 260 is an n+type layer. Accordingly, in such examples, dopants such as phosphorus, arsenic, and the like may be used. Alternate dopants and doping types are contemplated. The doping process may include an annealing step in some embodiments.

A passivation layer 3270 (as illustrated in FIG. 3J) of a suitable insulator such as, for example, silicon dioxide, is then isotropically deposited using a suitable method. Passivation layer 3270 is deposited such that at least a portion of the sidewalls of pillar structures 3250a and 3250b are covered by the insulator. Suitable insulator materials include, but are not limited to, SiO₂, Si₃N₄, Al₂O₃, HfO₂, and the like, and/or any combinations thereof. Suitable methods for depositing the insulator include, but are not limited to, atomic layer deposition (ALD), PECVD, thermal oxidation, and the like.

FIG. 3K illustrates a sacrificial layer 3020 formed using a suitable material (e.g., a resist) by dipping the top portion of the pillar structures into a liquid form of the material while holding the substrate upside down. A curing step by illuminating the UV light may be included while the device is in upside down position to solidify the coated material.

An electrically conductive material is then anisotropically deposited to form the electrically conductive layer 3265 (illustrated in FIG. 3L). The anisotropic deposition results in substantially no deposition of the conductive material on the sidewalls of the pillar structures. The electrically conductive material is, however, deposited on the recessed portion of passivation layer 3270 between pillar structures 3250a and 3250b. Any suitable anisotropic method such as, for example, sputtering, thermal evaporation, e-beam evaporation, or the like may be used for depositing electrically conductive material. Suitable materials include Al, Cr, Au, Ag, Cu, Ni, Pd, Pt, Ti, and the like, or any combinations thereof.

This is followed by lifting-off of sacrificial layer 3020 using a suitable process (e.g., dissolution in a solvent). This results in removal of the electrically conductive material from the top portion of the pillar structures, while leaving the electrically conductive material on the recessed portion of the substrate (on top of passivation layer 3270). The resulting structure is depicted in FIG. 3M. A cleaning step may be included in some embodiments to remove any possible remnants of the sacrificial layer or the electrically conductive material from the top portion of the pillar structures.

A laser ablation process can be used for creating contacts 3265c (illustrated in FIG. 3N) between electrically conductive layer 3265 and shell layer 3260 through passivation layer 3270. In this process, a laser beam of suitable frequency and power is focused on selected locations to ablate portions of passivation layer 3270 such that the electrically conductive material comes in direct contact with the heavily doped semiconductor material of shell layer 3260. A pulsed ytterbium fiber laser with 16 μJ at 532 nm wavelength and 20-600 kHz repetition rate may be used for the laser ablation process.

FIG. 3O illustrates an optical clad 3280 conformally deposited on the pillar structures and the recessed portion of the substrate (on top of electrically conductive layer 3265). Suitable materials for optical clad 3280 include, but are not limited to, transparent polymers such as polydimethyl siloxane (PDMS), polymethyl methacrylate (PMMA), polyethylene terephthalate (PET), and the like, and/or any combinations thereof; and doped or undoped metal oxides such as, Al₂O₃, HfO₂, SiO₂, MgF₂, SnO, doped SnO, ZnO, doped ZnO, and the like, and/or any combinations thereof. Other suitable transparent insulating materials are alternatively or additionally contemplated. Any suitable method may be used for depositing optical clad 3280. For example, transparent polymers may be spin-coated and metal oxides may be deposited using CVD.

FIG. 3P illustrates an UV removable adhesive 3030 (e.g., an acrylic PSA (pressure sensitive adhesives), a positive photoresist, modified acrylic, etc.) deposited using a suitable process such as, for example, spin coating, (followed by curing and/or annealing as needed), such that UV removable adhesive 3030 substantially encapsulates the pillar structures and covers the top portion of optical clad 3280 on the recessed portion of the substrate between the pillar structures. A transparent carrier substrate (e.g., a glass plate) 3035 is placed on top of the structure as illustrated in FIG. 3P. Carrier substrate 3035 may be any material that is significantly transparent to UV radiation.

Substrate 3210 is then separated from the single crystal silicon substrate 3001 by a suitable process. Because porous silicon layer 3005 is mechanically weak, in an embodiment, a mechanical pulling force may be applied to substrate 3210 for separating substrate 3210 from substrate 3001. Any remnants of the porous silicon material from layer 3005 can be removed using a suitable etch process such as, for example, etching using potassium hydroxide (KOH) of a suitable concentration. FIG. 3Q illustrates the device following separation from substrate 3001. In alternative embodiments, where porous silicon layer 3005 may be replaced by a layer of other suitable material(s) (e.g, photoresist), etching, or dissolution processes are also contemplated.

A second passivation layer 3208 (as illustrated in FIG. 3R) of a suitable insulator such as, for example, silicon dioxide, is then isotropically deposited using a suitable method. Passivation layer 3208 is deposited on the bottom portion on substrate 3210. Suitable insulator materials include, but are not limited to, SiO₂, Si₃N₄, Al₂O₃, HfO₂, and the like, and/or any combinations thereof. Suitable methods for depositing the insulator include, but are not limited to, atomic layer deposition (ALD), PECVD, thermal oxidation, and the like.

A dopant paste 3040 is then deposited on second passivation layer 3208 using a suitable method such as, for example, screen printing, inkjet printing, or any other like imprinting method on selected portions of passivation layer 3208 as illustrated in FIG. 3S. In an example of photovoltaic device 200, the backside contacts 215 are formed using a heavily doped p+type layer. Accordingly, for such a device, the dopant paste may be for example, aluminum, indium, or like dopants. Dopant is then diffused into substrate 3210 by selectively removing (e.g., using laser ablation) portions of passivation layer 3208 where dopant paste 3040 was deposited. This results in a localized heavily doped layer forming ohmic contacts 3215 at the opening created by removal of portions of passivation layer 3208 as illustrated in FIG. 3T.

A metal layer 3205 (illustrated in FIG. 3U) is then deposited, to form the backside electrode, using a suitable process. The device is then mounted on a suitable mounting substrate 320 (illustrated in FIG. 3V) using a suitable method depending on the material selected for the mounting substrate. Material for mounting substrate 320 may be selected from, for example, Steel, Al, Cu, ceramic, glass, plastic, or any other suitable material having a sufficient mechanical strength. Once mounted on mounted substrate 320, carrier substrate 3035 may be removed by exposing UV removable adhesive 3030 to an appropriate dose of UV radiation to leave behind the photovoltaic device 200 (as illustrated in FIG. 3W).

### Example 2

### A Photovoltaic Device Having Vertical Core-Shell Heterojunctions

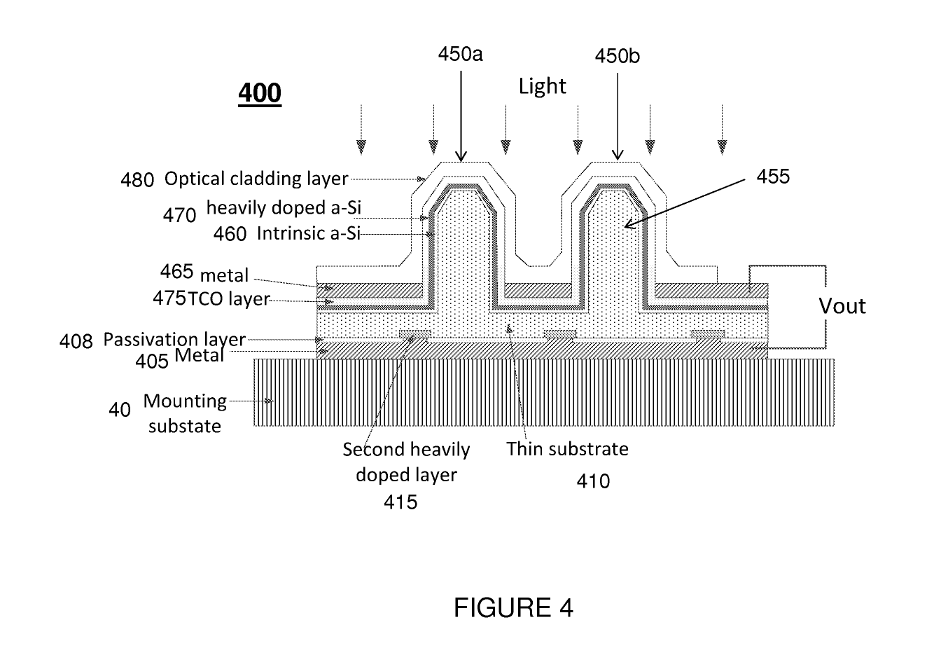

FIG. 4 illustrates a cross-section of a photovoltaic device 400 with a thin single crystal silicon substrate and vertical core-shell heterojunctions. Photovoltaic device 400 is mounted on a mounting substrate 40 and includes a metal layer 405 in contact with mounting substrate 40, and an intrinsic or a lightly p-doped single crystal silicon substrate 410 having heavily doped (p+) contacts 415 with bottom metal layer 405. Pillar structures 450a and 450b extend essentially perpendicularly from substrate 410 and include a semiconductor core 455, an intrinsic amorphous silicon shell layer 460, a heavily doped amorphous silicon layer 470, a transparent conducting oxide (TCO) layer 475 and an optical clad 480. An electrically conductive aluminum layer 465 is disposed in the space between neighboring pillar structures 450a and 450b, and between TCO layer 475 and optical clad 480. Electrically conductive layer 465 forms an ohmic contact between TCO layer 475 and a first (top) electrode (not explicitly shown) of photovoltaic device 400. Bottom metal (e.g., aluminum) layer 405 forms a contact for a second (bottom) electrode (not explicitly shown) of photovoltaic device 400. In some embodiments of this example, a second insulating passivation layer 408 may be included between substrate 410 and bottom metal layer 405.

As in case of photovoltaic device 200 of example 1, diameter (or a side-length) of pillar structures 450a and 450b may range from about 1 μm to about 10 μm, center-to-center distance between neighboring pillar structures may range from about 2 μm to about 20 μm, height of the pillar structures may range from about 1 μm to about 20 μm, thickness of substrate 410 may range from about 1 μm to about 50 μm, and thickness of clad layer 480 may range from about 100 nm to about 500 nm.

Intrinsic amorphous silicon layer 470 may have a thickness ranging from about 1 nm to about 10 nm and the thickness of heavily doped amorphous silicon layer 470 may range from about 5 nm to about 50 nm. TCO layer 475 may have a thickness ranging from about 10 nm to about 500 nm. Any suitable TCO material may be used. Examples of TCO materials include, but are not limited to, aluminum doped zinc oxide (AZO), indium doped tin oxide (ITO), fluorine doped tin oxide (FTO), and the like, or any combinations thereof. TCO layer 475 may be deposited using any suitable process such as, for example, spray pyrolysis, MOCVD, MOMBD, PLD, and the like, or any combinations thereof.

One of ordinary skill in the art will recognize that that depending on various factors discussed elsewhere herein, any thickness values between these ranges (including their limits) may be used in various embodiments.

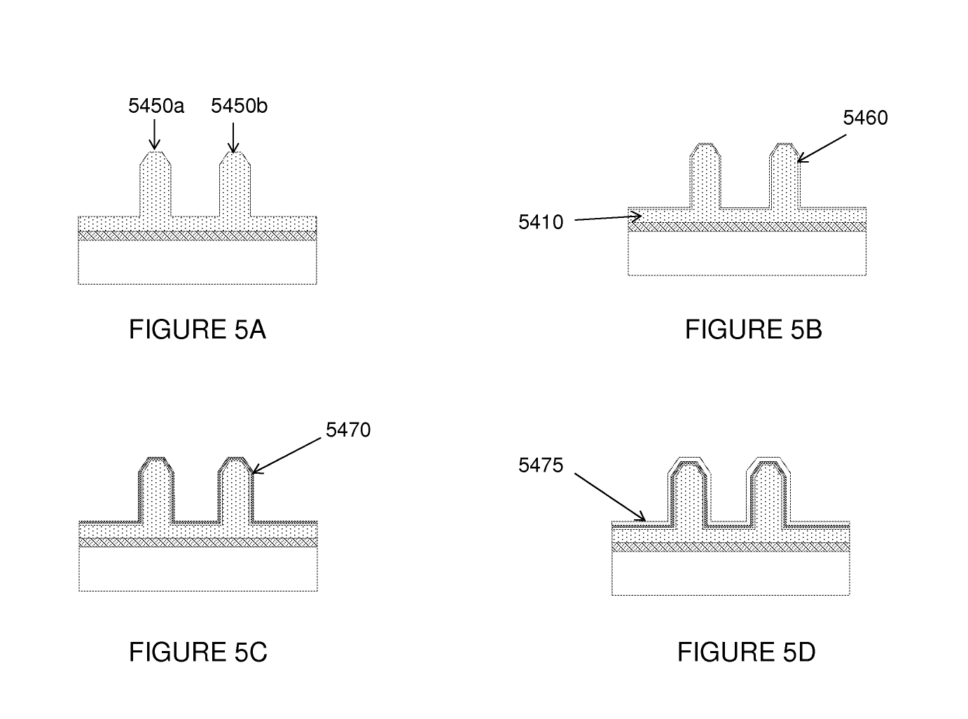

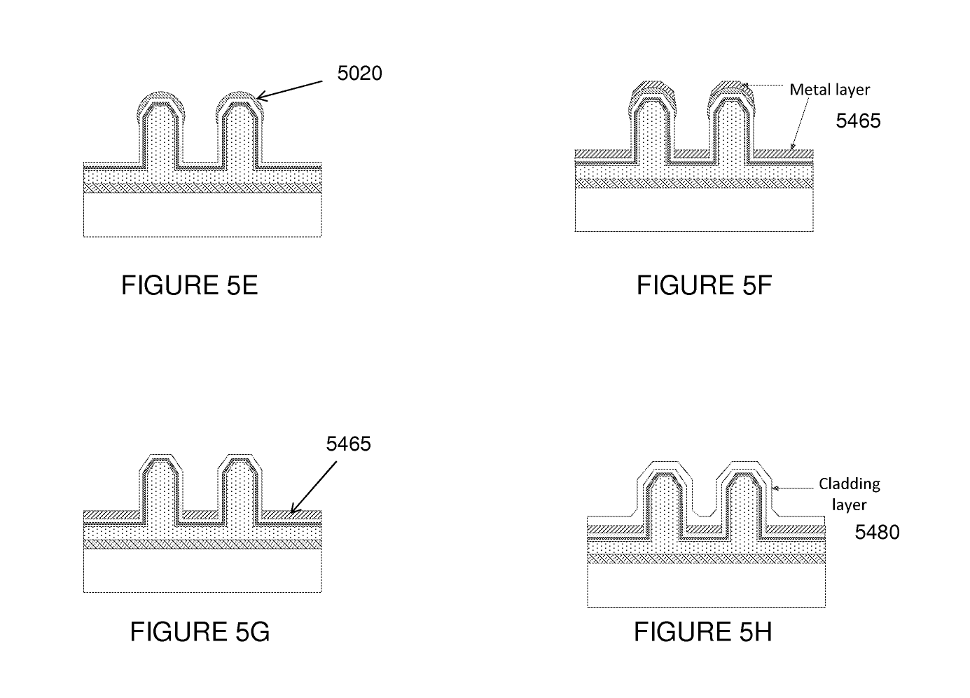

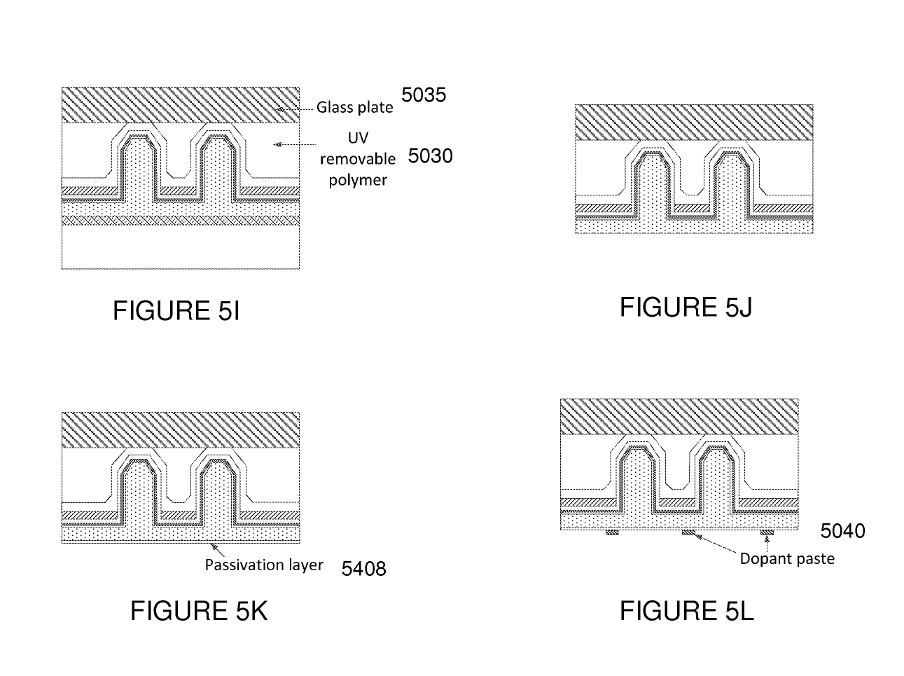

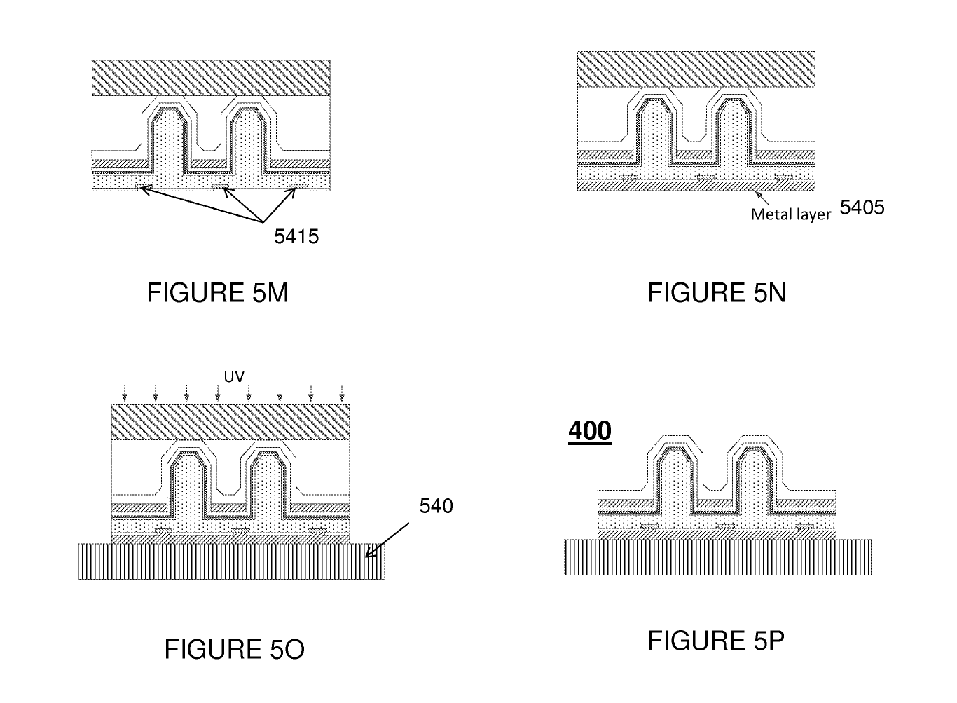

FIGS. 5A-5P schematically illustrate various steps during an exemplary process for fabrication of photovoltaic device 400 (or a like device) illustrated in FIG. 4, in accordance with various embodiments of the present disclosure.

FIG. 5A illustrates pillar structures 5450a and 5450b having a single crystalline silicon core made using a process similar to the one in Example 1. An intrinsic or lightly doped amorphous silicon layer 5460 is then deposited conformally (as illustrated in FIG. 5B) on the pillar surface as well as the recessed top surface using a suitable isotropic deposition method such as PECVD, hotwire CVD, or the like. This is followed by conformal deposition of a heavily doped amorphous silicon layer 5470 (as illustrated in FIG. 5C), using a suitable process, on the surface of the pillar structures as well as the recessed top surface of the substrate 5410. It is contemplated that the same process as that used for deposition of intrinsic amorphous silicon layer 5460 may be used for depositing heavily doped amorphous silicon layer 5470.

A suitable TCO material is then deposited conformally on the structures using a suitable method (e.g., spray pyrolysis, sputtering, etc.) to form a TCO layer 5475 as illustrated in FIG. 5D. FIG. 5E illustrates a sacrificial layer 5020 deposited on the top portion of the pillar structures using a process similar to one described for depositing layer 3020 of Example 1. A suitable metal is then deposited between the pillar structures to form metal layer 5465 which forms ohmic contact between the TCO layer and a first (top) electrode of the photovoltaic device. Metal layer 5465 is illustrated in FIG. 5F. FIG. 5G illustrates metal layer 5465 following the removal of sacrificial layer 5020 (and cleaning, if needed). An optical clad layer 5480 is then deposited conformally and isotropically on the structure using suitable methods. FIG. 5H depicts the structure with optical clad layer 5480.

Materials and methods used for deposition of the metal layer, removal (and/or cleaning) of the sacrificial layer, and deposition of the optical clad layer are the same as those used for respective process in Example 1. Similarly, materials and methods for subsequent steps including deposition of UV removable adhesive 5030, addition of carrier substrate 5035, removal of the crystalline silicon substrate 5001, deposition of second (backside) passivation layer 5408, disposing of dopant paste 5040, formation of localized heavily doped (backside) ohmic contacts 5415, deposition of backside metal layer 5405, mounting of the device on a mounting substrate 540 and removal of carrier substrate 5035 can be the same as those described with respect to Example 1. FIGS. 51-5P illustrate photovoltaic device 400 in various stages of fabrication.

### Example 3

### A Photovoltaic Device with Thin Gallium Arsenide Substrate and Vertical Core-Shell p-n Junctions

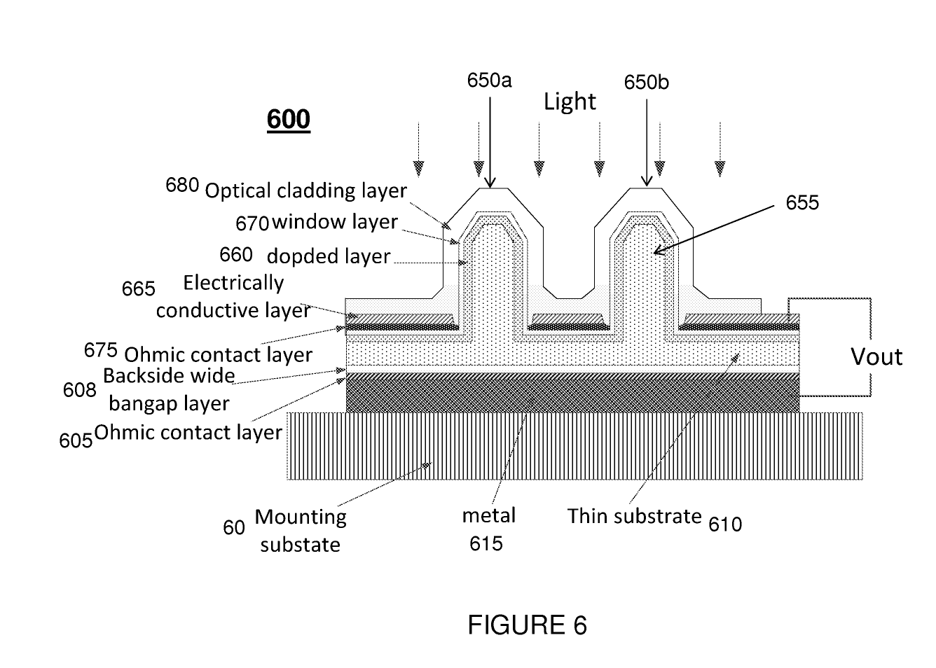

FIG. 6 illustrates a cross-section of a photovoltaic device 600 with a thin gallium arsenide substrate and vertical core-shell p-n junctions. Photovoltaic device 600 is mounted on a mounting substrate 60 and includes an ohmic contact layer 605 in contact with a metal layer 615 which is in contact with mounting substrate 60, and single crystal gallium arsenide substrate 610. Pillar structures 650a and 650b extend essentially perpendicularly from substrate 610 and include a semiconductor core 655, a doped (n+) (e.g., epitaxially grown) shell layer 660, a window layer 670 and an optical clad 680. A metal layer 665 is disposed in the space between neighboring pillar structures 650a and 650b, and between window layer 670 and optical clad 680. Ohmic contact layer 675 forms an ohmic contact between window layer 670 and metal layer 665, which forms an electrical contact for first electrode (not explicitly shown) of photovoltaic device 600. Bottom metal (e.g., aluminum) layer 615 forms an electrical contact for a second electrode (not explicitly shown) of photovoltaic device 600. In some embodiments of this example, a backside wide bandgap layer 608 and a backside ohmic contact layer 605 may be included between substrate 610 and bottom metal layer 615.

As in case of photovoltaic device 200 of example 1, diameter (or a side-length) of pillar structures 650a and 650b may range from about 1 μm to about 10 μm, center-to-center distance between neighboring pillar structures may range from about 2 μm to about 20 μm, height of the pillar structures may range from about 1 μm to about 20 μm, and thickness of clad layer 480 may range from about 100 nm to about 500 nm.

Thickness of substrate 610 may range from about 0.2 μm to about 30 μm. Thinner substrates may be sufficient for III-V semiconductor materials because these materials have stronger absorption than silicon due to their direct bandgap. Thickness of doped layer 660 may range from about 100 nm to about 500 nm. Window layer 670 may have a thickness ranging from about 10 nm to about 100 nm. Backside wide bandgap layer 608 may have a thickness of about 50 nm to about 500 nm and ohmic contact layers 605 and 675 may have a thickness ranging from about 0.01 μm to about 0.5 μm.

One of ordinary skill in the art will recognize that that depending on various factors discussed elsewhere herein, any thickness values between these ranges (including their limits) may be used in various embodiments.

Substrate 610 may alternatively, or additionally, be any III-V semiconductor. Likewise, in various embodiments, material for substrate 610 may be chosen from, for example, a II-VI semiconductor, any other binary semiconductor, a tertiary semiconductor, a quaternary semiconductor, and the like, or any combinations thereof.

Table 1 shows examples of materials for various layers that may be used for making photovoltaic device 600.

TABLE 1
Examples of materials for various layers of photovoltaic device 600.

| Name | Example |
|---|---|
| Window layer | Al_{0.4}Ga_{0.6}As, InGaP, AlInP |
| Wide bandgap layer | Al_{0.3}Ga_{0.7}As, InGaP, AlInP, AlGaInP |
| Ohmic contact layer | Heavily doped GaAs, InP |

Process for making photovoltaic device 600 is substantially similar to the process for making photovoltaic devices 200 and 400 with suitable modifications to incorporate differences in materials and thicknesses of various layers. For example, photovoltaic device 600 does not have insulating passivation layers, and as such, does not require an ohmic contact layer to provide contact through such passivation layers. Accordingly, process for making photovoltaic device 600 may not include a laser ablation step. Other modifications will be readily apparent to one of ordinary skill in the art.

The foregoing detailed description has set forth various embodiments of the devices and/or processes by the use of diagrams, flowcharts, and/or examples. Insofar as such diagrams, flowcharts, and/or examples contain one or more functions and/or operations, it will be understood by those within the art that each function and/or operation within such diagrams, flowcharts, or examples can be implemented, individually and/or collectively, by a wide range of hardware, software, firmware, or virtually any combination thereof.

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

All references, including but not limited to patents, patent applications, and non-patent literature are hereby incorporated by reference herein in their entirety.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A photovoltaic device comprising:
a substrate comprising a semiconductor material;
one or more core structures, each extending essentially perpendicularly from a first surface of the substrate such that the core structures and the substrate form a single crystal;
a shell layer disposed at least on a portion of a sidewall of the core structures and on the first surface; and
a conductive layer disposed between adjacent core structures,
wherein the conductive layer forms an ohmic contact with the shell layer.

2. The photovoltaic device of claim 1, wherein the substrate comprises one or more of a group IV single crystalline semiconductor, a group IV polycrystalline semiconductor, a group IV porous semiconductor, a single crystalline group III-V semiconductor, a single crystalline group II-VI semiconductor, and a single crystalline quaternary semiconductor.

3. The photovoltaic device of claim 1, wherein the substrate and at least one of the heavily doped semiconductor shell layer comprise one of the following doping profiles:
(i) the substrate is p type and the shell layer is n+type;
(ii) the substrate is n type and the shell layer is p+type.

4. The photovoltaic device of claim 1, wherein the one or more shell layers further comprise an optically transparent clad layer and a first layer.

5. The photovoltaic device of claim 4, wherein the each of the one or more core structures, the first layer comprising an intrinsic semiconductor, and the heavily doped semiconductor shell layer form a core-shell hetero-junction.

6. The photovoltaic device of claim 4, further comprising a second layer comprising a transparent conducting material disposed prior to disposing the optically transparent clad layer.

7. The photovoltaic device of claim 1, further comprising a first electrically conducting material disposed in electrical contact with the heavily doped semiconductor shell layer between neighboring core structures.

8. The photovoltaic device of claim 1, further comprising a second electrically conducting material disposed in electrical contact with a second surface of the substrate opposite the first surface.

9. The photovoltaic device of claim 8, further comprising a passivation layer disposed on the second surface of the substrate, wherein the passivation layer covers a portion of the second surface of the substrate not in contact with the second electrically conducting material.

10. The photovoltaic device of claim 1, wherein the substrate has a thickness of about 0.2 μm to about 50 μm.

11. The photovoltaic device of claim 1, wherein an aspect ratio of each of the one or more core structures is greater than one, aspect ratio being defined as a ratio of a dimension perpendicular to the substrate to a dimension parallel to the substrate.

12. The photovoltaic device of claim 1, wherein the one or more core structures have a cross-section including one or more of a circle, an ellipse, a convex polygon, and a mesh.

13. The photovoltaic device of claim 1, wherein neighboring core structures are separated by a distance of less than about 50 μm.

14. A method of making a device, the method comprising:
obtaining a plurality of core structures, each extending essentially perpendicularly from a substrate such that the substrate and the plurality of core structures form a single crystal;
disposing a shell layer adjacent at least a portion of a sidewall of each of the plurality of core structures;
disposing a passivation layer substantially encapsulating the shell layer;
disposing a conductive layer between neighboring core structures substantially encapsulating the passivation layer; and
forming an ohmic contact between the conductive layer and the shell layer between the adjacent core structures by ablating the passivation layer using laser ablation.

15. The method of claim 14, wherein the substrate comprises one or more of a group IV single crystalline semiconductor, a group IV polycrystalline semiconductor, a group IV porous semiconductor, a single crystalline group III-V semiconductor, a single crystalline group II-VI semiconductor, and a single crystalline quaternary semiconductor.

16. The method of claim 14, wherein the substrate and the shell layer comprise one of the following doping profiles:
(i) the substrate is p type and the shell layer is n+type;
(ii) the substrate is n type and the shell layer is p+type.

17. The method of claim 14, wherein the substrate has a thickness of about 0.2 μm to about 50 μm.

18. The method of claim 14, wherein the shell layer comprises a heavily doped semiconductor shell layer.

19. The method of claim 14, wherein an aspect ratio of each of the one or more core structures is greater than one.

20. The method of claim 14, wherein the plurality of core structures have a cross-section including one or more of a circle, an ellipse, a convex polygon, and a mesh.

21. The method of claim 14, wherein the shell layer further comprises an optically transparent clad layer and a first layer.

22. A method of making a photovoltaic device, the method comprising:
mounting on a first carrier substrate, a device substrate having a plurality of structures extending essentially perpendicularly from a first surface thereof;
disposing an ultra-violet (UV) removable adhesive on the device substrate such the plurality of structures and the first surface are substantially fully encapsulated by the UV removable adhesive;
contacting a second carrier substrate with the UV removable adhesive at a surface opposite the first surface;
unmounting the device substrate from the first carrier substrate to provide a second surface;
contacting the second surface with a conductive surface of a mounting surface; and
removing the second carrier substrate by exposing the UV removable adhesive to UV radiation.

23. The method of claim 22, wherein the second carrier substrate comprises glass.

24. The method of claim 22, wherein the device substrate comprises one or more of a group IV single crystalline semiconductor, a group IV polycrystalline semiconductor, a group IV porous semiconductor, a single crystalline group III-V semiconductor, a single crystalline group II-VI semiconductor, and a single crystalline quaternary semiconductor.

25. The method of claim 22, wherein each of the plurality of structures comprises a core-shell p-n junction configured to separate charge carriers in response to exposure to electromagnetic radiation.

26. The photovoltaic device of claim 1, wherein the shell layer is disposed on the first surface and between the adjacent core structures.

27. The photovoltaic device of claim 1, wherein the ohmic contact is between the adjacent core structures.

28. The photovoltaic device of claim 1, wherein the ohmic contact is only between the adjacent core structures.
